(19) United States
(12) Patent Application Publication
(10) Pub. No.: US 2021/0384371 A1
(43) Pub. Date: Dec. 9, 2021

(54) SOLAR CELL MODULE

(71) Applicant: 3M INNOVATIVE PROPERTIES COMPANY, St. Paul, MN (US)

(72) Inventors: Yuting Wan, Shanghai (CN); Jiaying Ma, Cottage Grove, MN (US); Yiwen Chu, Shanghai (CN); Timothy N. Narum, Lake Elmo, MN (US); Mark B. O'Neill, Stillwater, MN (US)

(21) Appl. No.: 16/963,000

(22) PCT Filed: Jan. 30, 2019
(86) PCT No.: PCT/IB2019/050759

§ 371 Date: Jul. 17, 2020

(30) Foreign Application Priority Data
Jan. 30, 2018 (CN) 201810090052.0
Jan. 30, 2018 (CN) 201820162007.7

(51) Int. Cl. H01L 31/05; H01L 31/048; H01L 31/054

(52) U.S. Cl. CPC H01L 31/0512; H01L 31/0547; H01L 31/048

(57) ABSTRACT

Disclosed is a solar cell module, which comprises a solar cell module comprising a light transmitting element, a front encapsulant layer, a plurality of solar cells spaced from each other, a back encapsulant layer, and an encapsulation backsheet disposed in the module's thickness direction, the plurality of solar cells together forming a matrix which comprises a plurality of solar cell strings parallel with each other, each solar cell string being made up of a plurality of solar cells connected in series, there being a string gap formed between every two adjacent solar cell strings, and there being a cell gap formed between adjacent solar cells in each solar cell string, wherein the solar cell module further comprises a plurality of light redirecting films each of which comprises an optical structure, the light redirecting films being disposed on the solar cells' back surfaces opposite to their light receiving surfaces or the encapsulation backsheet's surface within the solar cell module, such that they spatially correspond to the string gaps and/or the cell gaps, and the optical structures being disposed to face the solar cell's back surfaces, such that the optical structures reflect light toward the interface between the light transmitting element and air, and the light is subsequently totally internally reflected back to the light receiving surfaces of the solar cells.

### TECHNICAL FIELD

The present invention relates to the technical field of photovoltaic products, and in particular to a solar cell module.

### BACKGROUND

As the environmental problems worsen, more people are pursuing clean energies. Solar energy, as a clean energy, has therefore attracted much more attention. A solar cell is a device for generating electricity by utilizing the solar energy.

Currently, the commonly seen solar cell comprises a cell body encapsulated by an encapsulation cover sheet and an encapsulation backsheet. Passing through the encapsulation cover sheet, the light is incident on the light receiving side of the cell body through; and the cell body transforms the light energy of such light into electrical energy.

Currently, the power generating efficiency of the solar cell is low; thus, the technical problem as to how to increase the power generating efficiency of the solar cell needs to be addressed urgently.

### SUMMARY

The goal of the present disclosure is to provide a solar cell module with a higher electricity generating efficiency.

To attain the above goal, as an aspect of the present disclosure, a solar cell module is provided. The solar cell module comprises a light transmitting element, a front encapsulant layer, a plurality of solar cells spaced from each other, a back encapsulant layer, and an encapsulation backsheet disposed in the module's thickness direction, the plurality of solar cells together forming a matrix which comprises a plurality of solar cell strings parallel with each other, each solar cell string being made up of a plurality of solar cells connected in series, there being a string gap formed between every two adjacent solar cell strings, and there being a cell gap formed between adjacent solar cells in each solar cell string, wherein the solar cell module further comprises a plurality of light redirecting films each of which comprises an, the light redirecting films being disposed on the solar cells' back surfaces opposite to their light receiving surfaces or the encapsulation backsheet's surface within the solar cell module, such that they spatially correspond to the string gaps and/or the cell gaps, and the optical structures being disposed to face the solar cell's back surfaces, such that the optical structures reflect light toward the interface between the light transmitting element and air, and the light is subsequently totally internally reflected back to the light receiving surfaces of the solar cells.

Preferably, each of the light redirecting films is fixed to the opposing ends of corresponding two adjacent solar cells on their back side, or the encapsulation backsheet's surface within the solar cell module, by an adhesive or an adhesive tape.

Preferably, each of the optical structures comprises a plurality of triangular prisms, and a line perpendicular to a triangular prism's smallest cross section is defined as the triangular prism's trend, then the light redirecting films comprise at least one type of the following: (a) collimated-striped film, whose triangular prisms' trends are parallel to its lengthwise direction; (b) collimated-striped film, whose triangular prisms' trends are at an angle β with respect to its lengthwise direction.

Preferably, for a collimated-strip film, its angle β is within a range between 460 and 89°, preferably within a range between 500 and 80°.

Preferably, a maximum horizontal travelling path of light within the solar cell module is set to be d, and a light path reflected by a collimated-striped film is set to be L, then d=2×(Dg+De)×tan(α/2) and L=d′/cos β wherein preferably d=L and

$$β = arccos ( \frac{{d}^{′}}{2 \times ( Dg + De ) \times tan ( α / 2 )} ) ,$$

wherein d′ denotes a gap between solar cells, Dg denotes a thickness of the light transmitting element, De denotes a thickness of the front encapsulant layer, and α denotes a vertex angle of the triangular prisms in the collimated-striped film.

Preferably, the vertex angles of the triangular prisms are within a range between 1000 and 140°, preferably within a range between 1100 and 130°.

Preferably, the solar cell module is installed such that its longer edges are parallel to the horizontal plane, on at least one position spatially corresponding to the string gaps, there is disposed a transversely-striped film, and on at least one position spatially corresponding to the cell gaps, there is disposed a collimated-striped film.

Preferably, the solar cell module is installed such that its shorter edges are parallel to the horizontal plane, on at least one position spatially corresponding to the string gaps, there is disposed a collimated-striped film, and on at least one position spatially corresponding to the cell gaps, there is disposed a transversely-striped film.

Preferably, on at least one position spatially corresponding to the string gaps, and on at least one position spatially corresponding to the cell gaps, the transversely-striped films are disposed.

Preferably, on at least one position spatially corresponding to the string gaps, and on at least one position spatially corresponding to the cell gaps, the collimated-striped films are disposed.

Preferably, each of the light redirecting films comprises a substrate layer, and the optical layer is disposed on the substrate layer.

Preferably, the substrate layer comprises one or more polymer materials selected from a group consisting of cellulose acetate butyrate, cellulose acetate propionate, cellulose triacetate, polymethylmethacrylate, polyethylene terephthalate, polyethylene naphthalate, naphthalenedicarboxylic acid-based copolymers or mixtures, polyether sulfone, polyurethane, polycarbonate, polyvinyl chloride, syndiotactic polystyrene, cyclo-olefin polymers and silicone-based polymer materials, the thickness of the substrate layer is between 30 μm and 150 μm, and preferably between 40 μm and 100 μm.

Preferably, each of the optical structures comprises a plurality of triangular prisms and light reflecting layers disposed over the surfaces of the triangular prisms.

Preferably, the triangular prisms comprise a polymer material, the thickness of the optical structures is between 1 μm and 100 μm, preferably between 3 μm and 30 μm.

Preferably, the light reflecting layers comprise one or more of gold, aluminum, platinum, and titanium, the thickness of the light reflecting layers is between 30 nm and 100 nm, preferably between 35 nm and 60 nm.

When the solar module provided by the present invention is utilized, after the light penetrates through the light transmitting element 110, it is incident on an optical structure of the light redirecting film. The optical structure of the light redirecting film may reflect the incident light and change the direction of light propagation. Because the light is incident from the top position, the light redirecting film reflects the light upwards and towards the light transmitting element. When the light reflected by the light redirecting film enters the light transmitting element and propagates within the light transmitting element to the interface between the light transmitting element and the air, a total reflection occurs. The direction of light propagation changes again, and it ultimately is incident on the light receiving surface of the solar cell; and the solar cell utilizes such light for generating electricity.

It is thus clear that the solar cell module provided by the present invention has relatively high light utilization efficiency; and therefore the solar cell module has relatively high power generating efficiency.

### BRIEF DESCRIPTION OF THE DRAWINGS

The accompanying drawings are included to facilitate a better understanding of the present invention, and they constitute a part of this Description, and serve to explain the present invention together with the following embodiments. The drawings, however, are not to limit the present invention. In the accompanying drawings:

The accompanying drawings are included to facilitate a better understanding of the present invention, and they constitute a part of this Description, and serve to explain the present invention together with the following embodiments. The drawings, however, are not to limit the present invention. In the accompanying drawings:

FIG. 1 is a sectional view of the solar cell module according to a first embodiment provided by the present invention.

FIG. 2 is a sectional view of the solar cell module according to a second embodiment provided by the present invention.

FIG. 3 is a schematic illustration of the horizontally-installed solar cell module provided by an embodiment of the present invention.

FIG. 4 is an illustrative diagram of the vertically-installed solar cell module provided by an embodiment of the present invention.

FIG. 5 is a sectional view of the light redirecting film employed in accordance with an embodiment of the present invention.

FIG. 6 is a schematic illustration of a transversely-striped film employed in accordance with an embodiment of the present invention.

FIG. 7 is a schematic illustration of a collimated-striped film employed in accordance with an embodiment of the present invention.

### DETAILED DESCRIPTION

The present invention is described below in details with reference to the accompanying drawings. It should be understood that the embodiments described herein are for illustration and explanation purposes only and not intended to limit the present invention.

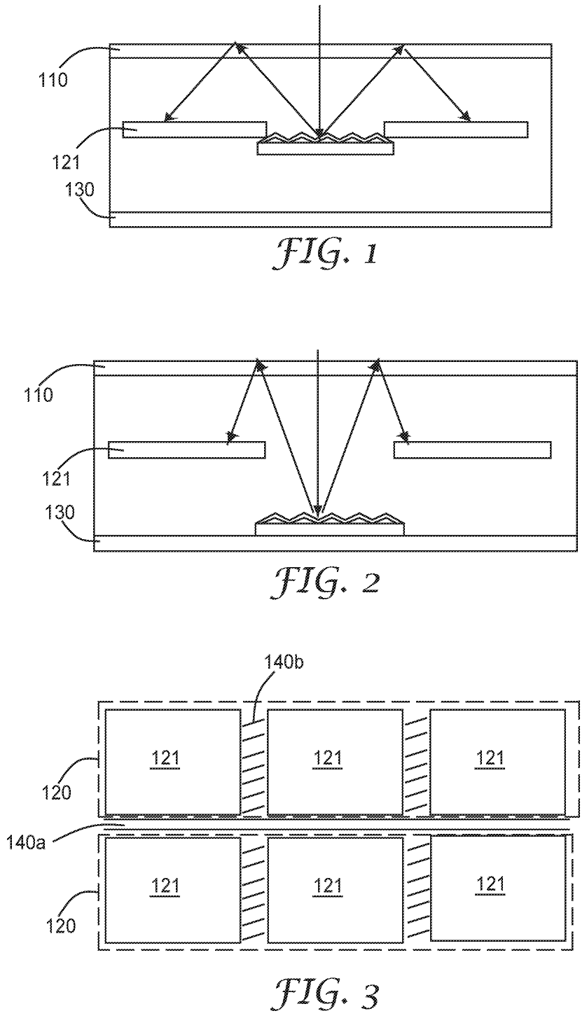

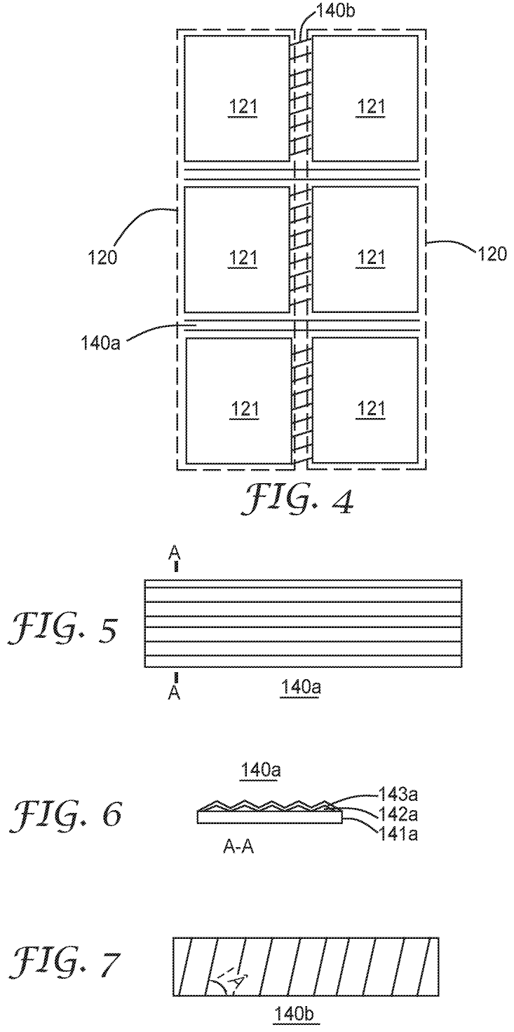

It needs to be explained that in the present invention, the location words “up” and “down” refer to the directions of “up” and “down” in FIG. 1, FIG. 2, and FIG. 6.

The present invention provides a solar cell module; as shown in FIG. 1 and FIG. 2, the solar cell module comprises a light transmitting element 110, a front encapsulant layer, a plurality of solar cells 121 spaced from each other, a back encapsulant layer, and an encapsulation backsheet 130 disposed in the module's thickness direction. The plurality of solar cells 121 together forming a matrix which comprises a plurality of solar cell strings parallel with each other, each solar cell string being made up of a plurality of solar cells connected in series, there being a string gap formed between every two adjacent solar cell strings, and there being a cell gap formed between adjacent solar cells in each solar cell string. The solar cell module further comprises a plurality of light redirecting films. Each of the light redirecting films comprises an optical structure, the light redirecting films being disposed on the solar cells' back surfaces opposite to their light receiving surfaces (as shown in FIG. 1) or the encapsulation backsheet's surface within the solar cell module (as shown in FIG. 2), such that they spatially correspond to the string gaps and/or the cell gaps, and the optical structures being disposed to face the solar cell's back surfaces opposite to their light receiving surfaces, such that the optical structures reflect light towards the interface between the light transmitting element and air, and the light is subsequently totally internally reflected back to the surfaces of the solar cells.

“The light redirecting films being disposed on the solar cells' back surfaces opposite to their light receiving surfaces” refers to that the edge portion of the light redirection film is fixed on the solar cells' back surfaces opposite to their light receiving surfaces, and the middle portion of the light redirection film corresponds to the string gap or the cell gap, so that the light penetrating through the light transmitting element 110 and the front encapsulant layer can incident on the light redirection film. When the solar module provided by the present invention is utilized, after the light penetrates through the light transmitting element 110, it is incident on an optical structure of the light redirecting film. The optical structure of the light redirecting film may reflect the incident light and change the direction of light propagation. As shown in FIG. 1 and FIG. 2, because the light is incident from the top position, the light redirecting film reflects the light upwards and towards the light transmitting element 110. When the light reflected by the light redirecting film enters the light transmitting element 110, and propagates within the light transmitting element 110 to the interface between the light transmitting element 110 and the air, a total reflection occurs. The direction of light propagation changes again, and it ultimately is incident on the light receiving surface of the solar cell 121; and the solar cell 121 utilizes such light for generating electricity.

It is thus clear that the solar cell module provided by the present invention has relatively high light utilization efficiency; and therefore the solar cell module has relatively high power generating efficiency.

In the present invention, there is no particular specification with respect to how to dispose the light redirecting films on the solar cells' back surfaces opposite to their light receiving surfaces. For example, as a specific embodiment, each of the light redirecting films is fixed to the opposing ends of the two corresponding adjacent solar cells on their back side. Alternatively, as another specific embodiment, the light redirecting film may be fixed to the encapsulation backsheet's surface within the solar cell module by using an adhesive or an adhesive tape.

In the present invention, there is no particular specification with respect to the optical structure on each of the light redirecting films; for example, in the embodiments as shown in FIG. 1, FIG. 2, and FIG. 6, each of the optical structures comprises a plurality of triangular prisms; and a line perpendicular to a triangular prism's smallest cross section is defined as the triangular prism's trend; then the light redirecting films comprise at least one of the following: (a) a transversely-striped film (as shown in FIG. 5), whose triangular prisms' trends are parallel to its length direction; (b) a collimated-striped film (as shown in FIG. 7), whose triangular prisms' trends are at an angle β with respect to its length direction.

The solar cell module provided by the present invention is especially suitable to be installed in areas with 30° N latitude. During actual installation, the solar cell module may be tilted 30° towards the south; that is, the module and the ground form an angle of 30°; and the projection of the module on the ground in its normal direction faces due south. The interpretations of the other similar expressions used in the present disclosure are the same as the interpretations herein. The same solar cell module may comprise a transversely-striped film 140a as well as a collimated-refraction film strip 140b to reach the goals of having a maximum match between the movement scope of the sun and the reflection azimuth angle of the light redirecting film, and an increase in the power output of the solar cell module.

Preferably, for the collimated-strip film, the angle β formed by the triangular prisms' trends and the machining direction of the collimated-strip film (i.e., the length direction of the collimated-strip film, also the winding direction when generating the collimated-strip film) is within a range of between 46° and 89°, and preferably within a range of between 50° and 80°, so as to ensure the light incident on the collimated-strip film can all be reflected to the light receiving surface of the solar cell and utilized.

For the collimated-strip film, the greater the angle β is, the smaller the area of the light reflected by the collimated-strip film that is blocked by the solar cell will be. In order to ensure that the reflected light of the collimated-strip film is reflected to the light receiving surface of the solar cell instead of being reflected twice to the surface of the collimated-strip film, the optical path L reflected by the collimated-strip film does not exceed the maximum optical path d within the solar cell module. For incident light at an incident angle of 0°, equation (1) may be utilized to calculate the maximum propagating path of the light in a horizontal direction within the solar cell module:

d=2×(Dg+De)×tan(α/2) (1)

d is the maximum propagating path of the light within the solar cell module in the horizontal direction;
De is the thickness of the front encapsulant layer;
   Dg is the thickness of the light transmitting element;
α is the degree of the vertex angle of the trigonal prism in the light redirection film.

The optical path L reflected by the collimated-strip film may be calculated using the following equation (2):

L=d′/cos β (2)

d′ is the gap between the solar cells.

Preferably, the optical path L reflected by the collimated-strip film is equal to the maximum optical path d in the horizontal direction within the solar cell module. In an embodiment where the gap between the cells is 3 mm, equation (1) and equation (2) may be utilized to arrive at the following equation under the optical circumstances (i.e., when the optical path L reflected by the collimated-strip film is equal to the maximum optical path d in the horizontal direction within the solar cell module),

$$β = arccos ( \frac{{d}^{′}}{2 \times ( Dg + De ) \times tan ( α / 2 )} )$$

it can then be calculated that β is 77° in this embodiment.

In order to ensure the light reflected by the optical structure can be totally internally reflected at the interface between the light transmitting element 110 and the air, preferably, the vertex angle of the prism of the optical structure is within a range of from 100° to 140°, and preferably, within a range of from 110° to 130°.

In a preferred embodiment provided by the present invention, the vertex angle of the prism is 120°. The solar cell module provided by the invention may be horizontally installed (as shown in FIG. 3) or vertically installed (as shown in FIG. 4).

In the solar cell module which is horizontally installed as shown in FIG. 3, the solar cell module is installed in such a way that the long edge of the solar cell module is parallel to the water level; and the transversely-striped film 140a is disposed on at least one position corresponding to the string gap; and the collimated-striped film 140a is disposed on at least one position corresponding to the cell gap.

In the solar cell module which is vertically installed as shown in FIG. 4, the solar cell module is installed in such a way that the short edge of the solar cell module is parallel to the water level; and the transversely-striped film 140a is disposed on at least one position corresponding to the string gap; and the collimated-striped film 140a is disposed on at least one position corresponding to the cell gap.

Certainly, the present invention is not limited to these two modes, the horizontally-installed solar cell module and the vertically-installed solar cell module.

As one embodiment of the present invention, the transversely-striped films are disposed on at least one position corresponding to the string gap and at least one position corresponding to the cell gap.

As another embodiment of the present invention, the collimated-striped films are disposed on at least one position corresponding to the string gap and at least one position corresponding to the cell gap.

In the present invention, there is no particular specification with respect to the particular structure of the light redirecting film. For ease of manufacture, preferably, each light redirecting film further comprises a substrate layer; and the optical structure is disposed on the substrate layer.

In this invention, the light redirecting film can also include a bonding layer; and this bonding layer and the optical structure are receptively disposed on both sides of the substrate layer in the thickness direction. An adhesive can be used to bond the light redirecting film with the solar cell.

The adhesive can be a pressure sensitive adhesive or a hot melt glue. For example, the adhesive may be an ethylene-vinyl acetate polymer, acrylic acid, acrylate, or other hot melt adhesives. The thickness of the adhesive is between 10 micrometers and 75 micrometers; preferably, the thickness of the adhesive layer may be between 20 micrometers and 50 micrometers.

The optical structure further comprises a reflective layer disposed on the surface of the optical structure. As shown in FIG. 6, the optical structure comprises triangular prisms 142a and a reflective layer 143a disposed on the side of the triangular prisms 142a.

As a preferred embodiment of the present invention, the substrate layer comprises one or a plurality of polymeric materials selected from the group consisting of: cellulose acetate butyrate, cellulose-acetate propionate, cellulose triacetate, poly(methyl)acrylate, polyethylene glycol terephthalate, polynaphthalene diol ester; copolymers or mixtures based on naphthalene dicarboxylic acid, copolymer of polyethersulfone, polyurethane, polycarbonate, polyvinyl chloride, syndiotactic polystyrene, cycloolefin as well as materials based on organosilicone.

Preferably, the thickness of the substrate layer is between 30 μm and 150 μm, more preferably the thickness of the substrate layer is between 40 μm and 100 μm.

For ease of manufacture, preferably, the materials for the triangular prisms of the optical structure include polymer materials. The thickness of the optical structure is between 1 μm and 100 μm, and preferably between 3 μm and 30 μm.

The material for the reflective layer may be a metallic material. The metallic material may be deposited on the triangular prism through sputtering to obtain the reflective layer.

For higher reflectivity, preferably the materials for the reflective layer includes one or a plurality of materials selected from the group consisting of gold, aluminum, platinum, and titanium.

For ease of manufacture, preferably the thickness of the reflective layer is between 30 nm and 100 nm; and more preferably, the thickness of the reflective layer is between 35 nm and 60 nm.

In the present invention, there is no particular specification with respect to the materials for the front encapsulant layer and the back encapsulant layer. For example, ethylene-vinyl acetate copolymer (i.e., EVA) material may be used to make the front encapsulant layer and the back encapsulant layer.

For an array comprising solar cells with a thickness of 0.2 mm, a front encapsulant layer with a thickness of 0.5 mm and a back encapsulant layer with a thickness of 0.5 mm may be used for its encapsulation.

The light transmitting element 110 may be made with a solar high-light-transmitting embossed glass; and a black backsheet (e.g., the black backsheet made by JinkoSolar Holding Co., Ltd.) may be utilized to manufacture the encapsulation backsheet 130. For an array comprising solar cells having a thickness of 0.2 mm, the thickness of the light transmitting element 110 may be 3.2 mm. Likewise, the thickness of the encapsulation backsheet 130 may also be 3.2 mm.

As a preferred embodiment, the solar cell module may comprise 60 solar cells. The size of the solar cell may be 156 mm×156 mm. In this embodiment, the solar cell module comprises 6 cell strings, each of which comprising 10 cells. In the present invention, there is no particular specification with respect to the size of the row gap and string gap. For example, as a preferred embodiment, the width of the string gap is the same as the width of the cell gap, thereby facilitating the configuration. Specifically, the width of the string gap may be between 1 mm and 20 mm. Furthermore, the width of the cell gap may also be between 1 mm and 200 mm.

However, the present invention is not limited thereto. For example, for a half-piece solar cell module, the size of the cell may be 156 mm×78 mm. The encapsulated solar cell module may be 1.6 m×0.99 m.

### EMBODIMENTS

### Embodiment 1

The solar cell module comprises a light transmitting element 110, a front encapsulant layer made of EVA materials, an array formed by a plurality of solar cells, a back encapsulant layer made of EVA materials, and an encapsulation backsheet 130 disposed in sequence along the module's thickness direction. The light transmitting element 110 may be made with solar high-light-transmitting embossed glass; and the encapsulation backsheet 130 may be made with a black backsheet produced by JinkoSolar Holding Co., Ltd. The thickness Dg of the light transmitting element 110 and the thickness of the encapsulant backsheet 130 are both 3.2 mm. The thickness De of the front encapsulant layer is 0.5 mm. The array of solar cells consists of 6 cell strings, each of which comprises 10 cells; and the cell strings are connected in series through tabbing ribbons. Furthermore, the solar cell module that is horizontally installed comprises 5 string gaps and 9 cell gaps. The string gaps 140a correspond to the transversely-striped film, and the cell gaps correspond to the collimated-striped film 140b. The string gap Dₛₑᵣᵢₐₗ is 3 mm and the cell gap D_{cell} is also 3 mm.

The thickness of the cell is 0.2 mm. The light utilization efficiency η of the employed light redirecting film is 80%, which is a percentage defined by dividing the short-circuit current generated by the light radiation of a unit strength through the light redirecting film by the short-circuit current generated by the light radiation on the solar cell of a unit strength; the definition of the light utilization efficiency η in the equation below is the same as the definition of the light utilization efficiency η herein; and the light redirecting film is disposed on the surface of the encapsulation backsheet that is located within the module.

As shown in FIG. 4a, the transversely-striped film comprises a substrate layer 141a, a light redirecting film 142a of a triangular prism shape, and a reflective layer 143a. The vertex angle of the prism of the light redirecting film employed is 120°; and the reflective layer is made of aluminum. In the collimated-striped film 140b, the angle between the length direction of the light redirecting film and the length direction of the collimated-striped film is 77°; and the vertex angle β of its triangular prism is also 120°.

The solar cell module is mounted in the area with 30° latitude (equivalent to Shanghai in China); therefore, the installation of the solar cell module tilts 300 towards the south.

In the solar cell modules, the quantitative expression corresponding to the area that is blocked by the solar cellis S1=De×tan(α/2);

the quantitative expression corresponding to the effective reflection area of the transversely-striped film is S2=D−De×tan(α/2); herein, the D is the string gap Dₛₑᵣᵢₐₗ or cell gap D_{cell} according to the actual situation;

the quantitative expression corresponding to the effective reflection area of the collimated-striped film is S3=D−De×tan(α/2)×cos β; herein, the D is the string gap Dₛₑᵣᵢₐₗ or cell gap D_{cell} according to the actual situation; and the β is the angle as noted above, which is formed by the triangular prisms' trends of the optical structure of the collimated-striped film and the length direction of the collimated-striped film.

The area S4 of the 5 string gaps is 5×1.6 m×3 mm, where 1.6 m is the length of the module;

The area S5 of the 9 cell gaps is 9×0.99 m×3 mm, where 0.99 m is the width of the module;

The area S0 of the module is 1.6 m×0.99 m.

Thus, when compared with the equivalent solar cell modules without the light redirection films, the power gain of the solar cell module provided by Embodiment 1 is as follows:

$$Δ 1 = \frac{\begin{matrix}\frac{{D}_{serial} - De \times tan ( α / 2 )}{{D}_{serial}} \times S 4 + \\ \frac{{D}_{cell} - De \times tan ( α / 2 ) \times cos β}{{D}_{cell}} \times S 5\end{matrix}}{S 0} \times η = 2.21 \%$$

where De is the thickness for the front encapsulant layer; α is the vertex angle of the prism of the microstructure; Dₛₑᵣᵢₐₗ is the string gap, D_{cell} is the cell gap, β is the angle formed by the triangular prisms' trends and the length direction of the collimated-striped film; and η is the light utilization efficiency of the light redirecting film; and in this embodiment, it is 80%; the definitions of the various items in the following embodiments are the same as the definitions of the various item in this embodiment;

### Embodiment 2

Embodiment 2 provides a solar cell module, and when compared with Embodiment 1, the difference therebetween lies in that the solar cell module of Embodiment 2 is a solar cell module that is vertically installed. The cell gaps are disposed vertically, and the string gaps are disposed horizontally. The transversely-striped film is disposed at the location corresponding to the cell gaps; and the collimated-striped film is disposed at the location corresponding to the string gaps.

Through the following simulation calculation, one learns that, when compared with the equivalent solar cell modules without the light redirecting films, the power gain of the solar cell module is as follows:

$$Δ 2 = \frac{\begin{matrix}\frac{{D}_{cell} - De \times tan ( α / 2 )}{{D}_{cell}} \times S 5 + \\ \frac{{D}_{serial} - De \times tan ( α / 2 ) \times cos β}{{D}_{serial}} \times S 4\end{matrix}}{S 0} \times η = 2.2 \%$$

Herein η is also 80%.

### Embodiment 3

Embodiment 3 provides a solar cell module. When compared with Embodiment 1, the difference therebetween lies in that the transversely-striped films are disposed both in the cell gaps and string gaps of the solar cell module of Embodiment 3.

Through the following simulation calculation, one learns that, when compared with the equivalent solar cell modules without the light redirecting films, the power gain of the solar cell module is as follows:

$$Δ 3 = \frac{\begin{matrix}\frac{{D}_{serial} - De \times tan ( α / 2 )}{{D}_{serial}} \times S 4 + \\ \frac{{D}_{cell} - De \times tan ( α / 2 )}{{D}_{cell}} \times S 5\end{matrix}}{S 0} \times η = 1.96 \%$$

Herein η is also 80%.

### Embodiment 4

Embodiment 4 provides a solar cell module. When compared with Embodiment 1, the difference therebetween lies in that the collimated-striped films are disposed both in the cell gaps and string gaps of the solar cell module of Embodiment 4.

Through the following simulation calculation, one learns that, when compared with the equivalent solar cell modules without the light redirecting films, the power gain of the solar cell module is as follows:

$$Δ 4 = \frac{\begin{matrix}\frac{{D}_{serial} - De \times tan ( α / 2 ) \times cos β}{{D}_{serial}} \times S 4 + \\ \frac{{D}_{cell} - De \times tan ( α / 2 ) \times cos β}{{D}_{cell}} \times S 5\end{matrix}}{S 0} \times η = 2.37 \%$$

Herein η is also 80%.

It can be understood that, the above embodiments are only exemplary embodiments employed for illustration of principles of the present invention, and do not limit the present invention. For those of ordinary skill in the art, various variations and improvements may be made without departing from the spirit and essence of the present invention, and these variations and improvements are also considered as falling within the protection scope of the present invention.

1. A solar cell module comprising a light transmitting element, a front encapsulant layer, a plurality of solar cells spaced from each other, a back encapsulant layer, and an encapsulation backsheet disposed in the module's thickness direction, the plurality of solar cells together forming a matrix which comprises a plurality of solar cell strings parallel with each other, each solar cell string being made up of a plurality of solar cells connected in series, there being a string gap formed between every two adjacent solar cell strings, and there being a cell gap formed between adjacent solar cells in each solar cell string, wherein the solar cell module further comprises a plurality of light redirecting films each of which comprises an optical structure, the light redirecting films being disposed on the solar cells' back surfaces opposite to their light receiving surfaces or the encapsulation backsheet's surface within the solar cell module, such that they spatially correspond to the string gaps and/or the cell gaps, and the optical structures being disposed to face the solar cell's back surfaces, such that the optical structures reflect light toward the interface between the light transmitting element and air, and the light is subsequently totally internally reflected back to the light receiving surfaces of the solar cells.

2. The solar cell module of claim 1, wherein each of the light redirecting films is fixed to the opposing ends of corresponding two adjacent solar cells on their back side, or the encapsulation backsheet's surface within the solar cell module, by an adhesive or an adhesive tape.

3. The solar cell module of claim 1, wherein each of the optical structures comprises a plurality of triangular prisms, and a line perpendicular to a triangular prism's smallest cross section is defined as the triangular prism's trend, then the light redirecting films comprise at least one type of the following: (a) transversely-striped film, whose triangular prisms' trends are parallel to its lengthwise direction; (b) collimated-striped film, whose triangular prisms' trends are at an angle β with respect to its lengthwise direction.

4. The solar cell module of claim 3, wherein for a collimated-strip film, its angle β is within a range between 46° and 89°, preferably within a range between 50° and 80°.

5. The solar cell module of claim 3, a maximum horizontal travelling path of light within the solar cell module is set to be d, and a light path reflected by a collimated-striped film is set to be L, then d=2×(Dg+De)×tan(α/2), and L=d′/cos β wherein preferably d=L, and
$$β = arccos ( \frac{{d}^{′}}{2 \times ( Dg + De ) \times tan ( α / 2 )} ) ,$$
wherein d′ denotes a gap between solar cells, Dg denotes a thickness of the light transmitting element, De denotes a thickness of the front encapsulant layer, and α denotes a vertex angle of the triangular prisms in the collimated-striped film.

6. The solar cell module of claim 3, wherein the vertex angles of the triangular prisms are within a range between 100° and 140°, preferably within a range between 110° and 130°.

7. The solar cell module of claim 3, wherein the solar cell module is installed such that its longer edges are parallel to the horizontal plane, on at least one position spatially corresponding to the string gaps, there is disposed a transversely-striped film, and on at least one position spatially corresponding to the cell gaps, there is disposed a collimated-striped film.

8. The solar cell module of claim 3, wherein the solar cell module is installed such that its shorter edges are parallel to the horizontal plane, on at least one position spatially corresponding to the string gaps, there is disposed a collimated-striped film, and on at least one position spatially corresponding to the cell gaps, there is disposed a transversely-striped film.

9. The solar cell module of claim 3, wherein on at least one position spatially corresponding to the string gaps, and on at least one position spatially corresponding to the cell gaps, the transversely-striped films are disposed.

10. The solar cell module of claim 3, wherein on at least one position spatially corresponding to the string gaps, and on at least one position spatially corresponding to the cell gaps, the collimated-striped films are disposed.

11. The solar cell module of claim 1, wherein each of the light redirecting films comprises a substrate layer, and the optical layer is disposed on the substrate layer.

12. The solar cell module of claim 11, wherein the substrate layer comprises one or more polymer materials selected from a group consisting of cellulose acetate butyrate, cellulose acetate propionate, cellulose triacetate, polymethylmethacrylate, polyethylene terephthalate, polyethylene naphthalate, naphthalenedicarboxylic acid-based copolymers or mixtures, polyether sulfone, polyurethane, polycarbonate, polyvinyl chloride, syndiotactic polystyrene, cyclo-olefin polymers and silicone-based polymer materials, the thickness of the substrate layer is between 30 μm and 150 μm, and preferably between 40 μm and 100 μm.

13. The solar cell module of claim 11, wherein each of the optical structures comprises a plurality of triangular prisms and light reflecting layers disposed over the surfaces of the triangular prisms.

14. The solar cell module of claim 3, wherein the triangular prisms comprise a polymer material, the thickness of the optical structures is between 1 μm and 100 μm, preferably between 3 μm and 30 μm.

15. The solar cell module of claim 13, wherein the light reflecting layers comprise one or more of gold, aluminum, platinum, and titanium, the thickness of the light reflecting layers is between 30 nm and 100 nm, preferably between 35 nm and 60 nm.
